(19) United States
(12) Patent Application Publication
(10) Pub. No.: US 2015/0049854 A1
(43) Pub. Date: Feb. 19, 2015

(54) SHIFT REGISTERS

(71) Applicant: SK hynix Inc., Icheon-si (KR)

(72) Inventor: Keun Soo SONG, Icheon-si Gyeonggi-do (KR)

(73) Assignee: SK hynix Inc., Icheon-si (KR)

(21) Appl. No.: 14/170,789

(22) Filed: Feb. 3, 2014

(30) Foreign Application Priority Data
Aug. 16, 2013 (KR) 10-2013-0097292

(51) Int. Cl. G11C 19/28

(52) U.S. Cl. CPC G11C 19/28
USPC 377/70

(57) ABSTRACT

Shift registers are provided. The shift register includes a first clock buffer and a second clock buffer. The first clock buffer inverts an input signal and a complementary input signal in response to a clock signal to generate a first output signal and a first complementary output signal. The second clock buffer inverts the first output signal and the first complementary output signal in response to the clock signal to generate a second output signal and a second complementary output signal.

### CROSS-REFERENCE TO RELATED APPLICATION

The present application claims priority under 35 U.S.C. 119(a) to Korean Application No. 10-2013-0097292, filed on Aug. 16, 2013, in the Korean Intellectual Property Office, which is incorporated herein by reference in its entirety.

### BACKGROUND

1. Technical Field

Example embodiments of the present disclosure relate generally to semiconductor devices, and more particularly to shift registers.

2. Related Art

Semiconductor devices may use a predetermined write latency and a predetermined additive latency to manage the flow of data going to and from external systems or external circuits. A write latency is a delay imposed when the external systems or external circuits read data in memory. For example, the write latency may be defined as the number of cycles of a system clock signal between a moment that a write command signal is inputted to a control pad and a moment that data, which will be written, is inputted to a data pad after the write command signal is inputted. For example, if the write latency is four, the data may be inputted to the data pad after four cycles of the system clock signal from the moment that write command signal is inputted. A processor uses column address strobe signals (hereinafter referred to as “CAS”) and row address strobe signals (hereinafter referred to as “RAS”) to read data from semiconductor memory devices. An additive latency AL may allows a read command signal or a write command signal to be issued prior to a RAS to CAS delay time tRCD, if the additive latency AL is less than the RAS to CAS delay time tRCD. Consequently, the read command signal or the write command signal cannot be issued prior to an active signal. The read command signal or the write command signal may be held for the time specified by the additive latency AL before it is internally issued to the semiconductor device. For example, if the additive latency AL is two, the read command signal or the write command signal may be inputted before two cycles of the system clock signal from a moment that the RAS to CAS delay time tRCD elapses after the active signal is inputted.

Information on the write latency and the additive latency AL may be predetermined and stored by a mode register set MRS. In order that data input/output (I/O) operations are performed with the predetermined write latency and the predetermined additive latency AL, the command signals and control signals have to be shifted. Thus, each of the semiconductor devices may include a shift register.

### SUMMARY

Various embodiments of the present invention are directed to shift registers.

According to an embodiment of the present invention, a shift register includes a first clock buffer and a second clock buffer. The first clock buffer inverts an input signal and a complementary input signal in response to a clock signal to generate a first output signal and a first complementary output signal. The second clock buffer inverts the first output signal and the first complementary output signal in response to the clock signal to generate a second output signal and a second complementary output signal.

According to an embodiment of the present invention, a shift register includes a first buffer configured to output a first complementary output signal generated by inverting an input signal in synchronization with a first edge of the clock signal through a first node, a second buffer configured to output a second output signal generated by inverting the first complementary output signal in synchronization with a second edge of the clock signal through a second node, a third buffer configured to output a first output signal generated by inverting a complementary input signal in synchronization with the first edge of the clock signal through a third node, and a fourth buffer configured to output a second complementary output signal generated by inverting the first output signal in synchronization with the second edge of the clock signal through a fourth node.

### BRIEF DESCRIPTION OF THE DRAWINGS

Embodiments of the present invention will become more apparent in view of the attached drawings and accompanying detailed description, in which:

FIG. 1 is a block diagram illustrating a shift register according to an embodiment of the present invention;

FIG. 2 is a circuit diagram illustrating a first clock buffer included in the shift register of FIG. 1;

FIG. 3 is a circuit diagram illustrating a second clock buffer included in the shift register of FIG. 1;

FIG. 4 is a timing diagram illustrating an operation of the shift register shown in FIGS. 1, 2 and 3; and

FIG. 5 is a block diagram illustrating a shift register according to an embodiment of the present invention.

### DETAILED DESCRIPTION OF THE EMBODIMENTS

Various embodiments of the present invention will be described more fully hereinafter with reference to the accompanying drawings. However, the embodiments described herein are for illustrative purposes only and are not intended to limit the scope of the present invention.

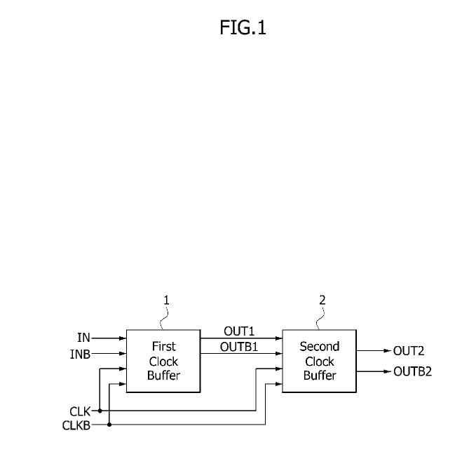

Referring to FIG. 1, a shift register according to an embodiment of the present invention may include a first clock buffer 1 and a second clock buffer 2. The first clock buffer 1 may generate a first output signal OUT1 and a first complementary output signal OUTB1 in response to an input signal IN, a complementary input signal INB, a clock signal CLK and a complementary clock signal CLKB. For example, the first clock buffer 1 may invert the input signal IN and the complementary input signal INB in response to the clock signal CLK and the complementary clock signal CLKB to generate the first complementary output signal OUTB1 and the first output signal OUT1. The second clock buffer 2 may generate a second output signal OUT2 and a second complementary output signal OUTB2 in response to the first output signal OUT1, the first complementary output signal OUTB1, the clock signal CLK and the complementary clock signal CLKB. For example, the second clock buffer 2 may invert the first output signal OUT1 and the first complementary output signal OUTB1 in response to the clock signal CLK and the complementary clock signal CLKB to generate a second complementary output signal OUTB2 and a second output signal OUT2. The clock signal CLK and the complementary clock signal CLKB may be supplied from an external device, for example, a memory controller.

In an embodiment of the present invention, the first clock buffer 1 may invert the input signal IN in synchronization with a falling edge of the clock signal CLK (i.e., a rising edge of the complementary clock signal CLKB) to generate the first complementary output signal OUTB1. Further, the first clock buffer 1 may invert the complementary input signal INB in synchronization with a falling edge of the clock signal CLK (i.e., a rising edge of the complementary clock signal CLKB) to generate the first output signal OUT1.

Moreover, the second clock buffer 2 may invert the first output signal OUT1 in synchronization with a rising edge of the clock signal CLK (i.e., a falling edge of the complementary clock signal CLKB) to generate the second complementary output signal OUTB2. Further, the second clock buffer 2 may invert the first complementary output signal OUTB1 in synchronization with a rising edge of the clock signal CLK (i.e., a falling edge of the complementary clock signal CLKB) to generate the second output signal OUT2.

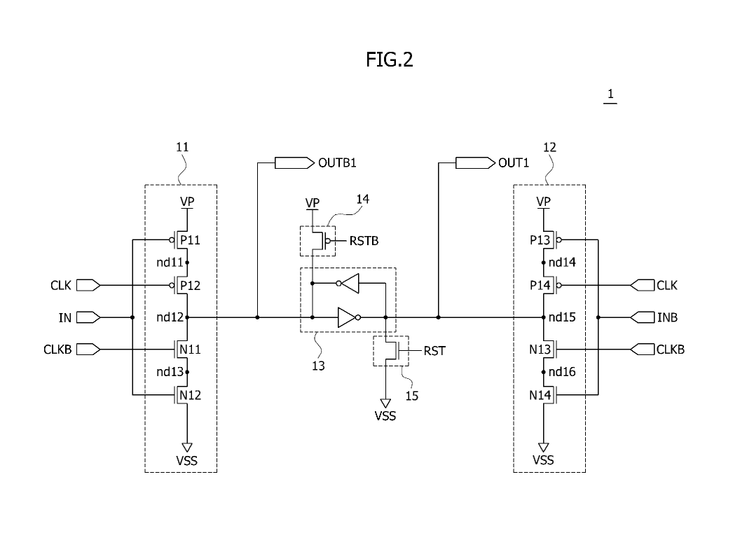

Referring to FIG. 2, the first clock buffer 1 may include a first buffer 11, a second buffer 12, a first latch unit 13, a first initialization element 14 and a second initialization element 15.

The first buffer 11 may include one or more PMOS transistors and one or more NMOS transistors which are coupled in series between a drive voltage VP terminal and a ground voltage VSS terminal. For example, the first buffer 11 may include a PMOS transistor P11 coupled between the drive voltage VP terminal and a node ND11, a PMOS transistor P12 coupled between the node ND11 and a node ND12, an NMOS transistor N11 coupled between the node ND12 and a node ND13, and an NMOS transistor N12 coupled between the node ND13 and the ground voltage VSS terminal. The PMOS transistor P11 may be turned on in response to the input signal IN, and the PMOS transistor P12 may be turned on in response to the clock signal CLK. Further, the NMOS transistor N11 may be turned on in response to the complementary clock signal CLKB, and the NMOS transistor N12 may be turned on in response to the input signal IN. The first buffer 11 may be configured to invert the input signal IN in synchronization with a falling edge of the clock signal CLK (i.e., a rising edge of the complementary clock signal CLKB) to generate the first complementary output signal OUTB1. The drive voltage VP may be an internal voltage generated in a semiconductor device, which includes the first clock buffer 1 and the second clock buffer 2 therein, or may be an external voltage supplied from an external device.

The second buffer 12 may include one or more PMOS transistors and one or more NMOS transistors which are coupled in series between the drive voltage VP terminal and the ground voltage VSS terminal. For example, the second buffer 12 may include a PMOS transistor P13 coupled between the drive voltage VP terminal and a node ND14, a PMOS transistor P14 coupled between the node ND14 and a node ND15, an NMOS transistor N13 coupled between the node ND15 and a node ND16, and an NMOS transistor N14 coupled between the node ND16 and the ground voltage VSS terminal. The PMOS transistor P13 may be turned on in response to the complementary input signal INB, and the PMOS transistor P14 may be turned on in response to the clock signal CLK. Further, the NMOS transistor N13 may be turned on in response to the complementary clock signal CLKB, and the NMOS transistor N14 may be turned on in response to the complementary input signal INB. The second buffer 12 may be configured to invert the complementary input signal INB in synchronization with a falling edge of the clock signal CLK (i.e., a rising edge of the complementary clock signal CLKB) to generate the first output signal OUT1.

The first latch unit 13 may be coupled between the node ND12 and the node ND15 to latch voltage levels of the node ND12 and the node ND15. The first initialization element 14 may drive the node ND12 in response to a complementary reset signal RSTB so that the node ND12 has the drive voltage VP. The second initialization element 15 may drive the node ND15 in response to a reset signal RST so that the node ND15 has the ground voltage VSS. The reset signal RST may have a logic “high” level to initialize the semiconductor device, and the complementary reset signal RSTB may have a logic “low” level to initialize the semiconductor device.

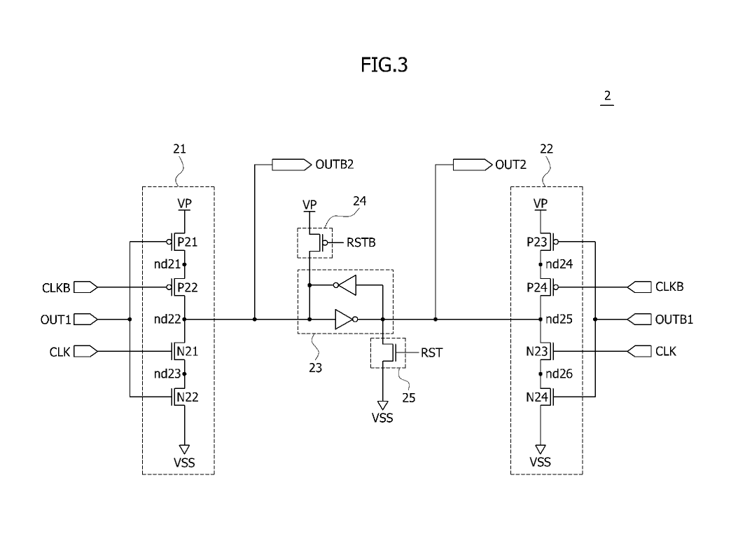

Referring to FIG. 3, the second clock buffer 2 may include a third buffer 21, a fourth buffer 22, a second latch unit 23, a third initialization element 24 and a fourth initialization element 25.

The third buffer 21 may include one or more PMOS transistors and one or more NMOS transistors which are coupled in series between a drive voltage VP terminal and a ground voltage VSS terminal. For example, the third buffer 21 may include a PMOS transistor P21 coupled between the drive voltage VP terminal and a node ND21, a PMOS transistor P22 coupled between the node ND21 and a node ND22, an NMOS transistor N21 coupled between the node ND22 and a node ND23, and an NMOS transistor N22 coupled between the node ND23 and the ground voltage VSS terminal. The PMOS transistor P21 may be turned on in response to the first output signal OUT1, and the PMOS transistor P22 may be turned on in response to the complementary clock signal CLKB. Further, the NMOS transistor N21 may be turned on in response to the clock signal CLK, and the NMOS transistor N22 may be turned on in response to the first output signal OUT1. The third buffer 21 may be configured to invert the first output signal OUT1 in synchronization with a rising edge of the clock signal CLK (i.e., a falling edge of the complementary clock signal CLKB) to generate the second complementary output signal OUTB2.

The fourth buffer 22 may include one or more PMOS transistors and one or more NMOS transistors which are coupled in series between a drive voltage VP terminal and a ground voltage VSS terminal. For example, the fourth buffer 22 may include a PMOS transistor P23 coupled between the drive voltage VP terminal and a node ND24, a PMOS transistor P24 coupled between the node ND24 and a node ND25, an NMOS transistor N23 coupled between the node ND25 and a node ND26, and an NMOS transistor N24 coupled between the node ND26 and the ground voltage VSS terminal. The PMOS transistor P23 may be turned on in response to the first complementary output signal OUTB1, and the PMOS transistor P24 may be turned on in response to the complementary clock signal CLKB. Further, the NMOS transistor N23 may be turned on in response to the clock signal CLK, and the NMOS transistor N24 may be turned on in response to the first complementary output signal OUTB1. The fourth buffer 22 may be configured to invert the first complementary output signal OUTB1 in synchronization with a rising edge of the clock signal CLK (i.e., a falling edge of the complementary clock signal CLKB) to generate the second output signal OUT2.

The second latch unit 23 may be coupled between the node ND22 and the node ND25 to latch voltage levels of the node ND22 and the node ND25. The third initialization element 24 may drive the node ND22 in response to the complementary reset signal RSTB so that the node ND22 has the drive voltage VP. The fourth initialization element 25 may drive the node ND25 in response to the reset signal RST so that the node ND25 has the ground voltage VSS.

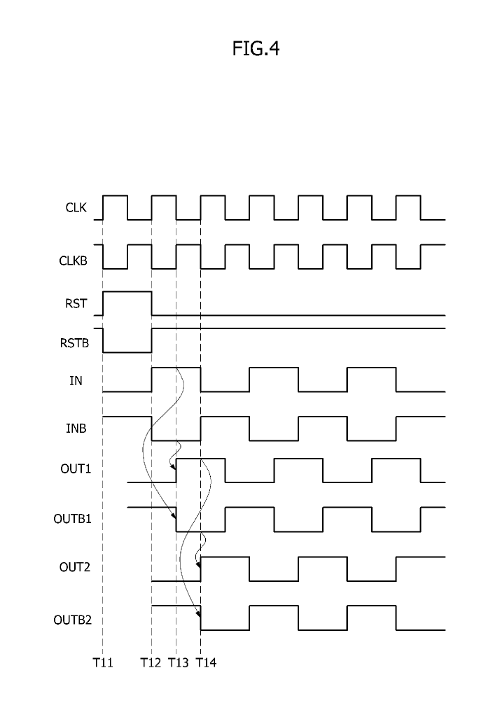

Hereinafter, an operation of the shift register shown in FIGS. 1, 2 and 3 will be described with reference to FIG. 4.

First, if the reset signal RST is generated to have a logic “high” level and the complementary reset signal RSTB is generated to have a logic “low” level during a period between points of time “T11” and “T12” to initialize the shift register, both the first and second output signals OUT1 and OUT2 may be initialized to have a logic “low” level and both the first and second complementary output signals OUTB1 and OUTB2 may be initialized to have a logic “high” level.

Next, at a point of time “T13, the input signal IN may be inverted to be outputted as the first complementary output signal OUTB1 and the complementary input signal INB may be inverted to be outputted as the first output signal OUT1, in synchronization with a falling edge of the clock signal CLK (i.e., a rising edge of the complementary clock signal CLKB). Thus, at the point of time “T13”, a level of the first output signal OUT1 may be changed from a logic “low” level into a logic “high” level and a level of the first complementary output signal OUTB1 may be changed from a logic “high” level into a logic “low” level.

Next, at a point of time “T14”, the first output signal OUT1 may be inverted to be outputted as the second complementary output signal OUTB2 and the first complementary output signal OUTB1 may be inverted to be outputted as the second output signal OUT2, in synchronization with a rising edge of the clock signal CLK (i.e., a falling edge of the complementary clock signal CLKB). Thus, at the point of time “T14”, a level of the second output signal OUT2 may be changed from a logic “low” level into a logic “high” level and a level of the second complementary output signal OUTB2 may be changed from a logic “high” level into a logic “low” level.

As described above, the shift register according to an embodiment of the present invention may invert both the input signal IN and the complementary input signal INB in synchronization with a falling edge of the clock signal CLK to generate the first output signal OUT1 and the first complementary output signal OUTB1. Further, the shift register according to an embodiment of the present invention may invert both the first output signal OUT1 and the first complementary output signal OUTB1 in synchronization with a rising edge of the clock signal CLK to generate and output the second output signal OUT2 and the second complementary output signal OUTB2. As such, the shift register according to an embodiment of the present invention may invert the input signal IN and the complementary input signal INB in sequential synchronization with a falling edge and a rising edge of the clock signal CLK, thereby stably generating the second output signal OUT2 and the second complementary output signal OUTB2 corresponding to differential output signals even in a high-speed operation.

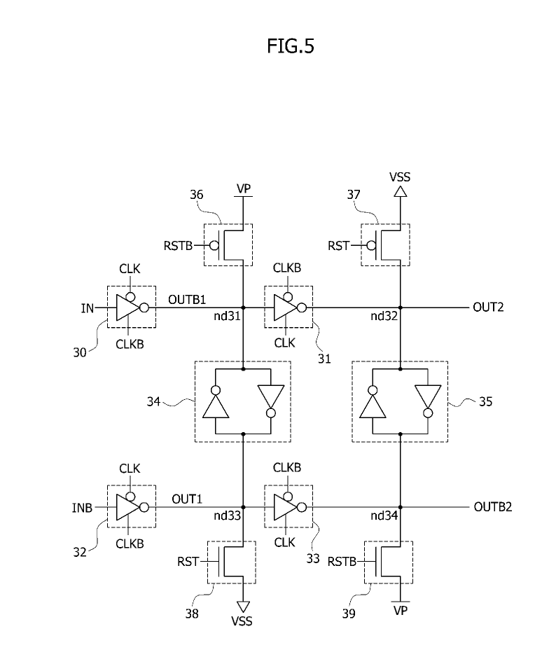

Referring to FIG. 5, a shift register according to an embodiment of the present invention may include a first buffer 30, a second buffer 31, a third buffer 32, a fourth buffer 33, a first latch unit 34, a second latch unit 35, a first initialization element 36, a second initialization element 37, a third initialization element 38 and a fourth initialization element 39.

The first buffer 30 may invert an input signal IN in synchronization with a falling edge of a clock signal CLK (i.e., a rising edge of a complementary clock signal CLKB) to generate a first complementary output signal OUTB1.

The second buffer 31 may invert the first complementary output signal OUTB1 in synchronization with a rising edge of a clock signal CLK (i.e., a falling edge of a complementary clock signal CLKB) to generate a second output signal OUT2.

The third buffer 32 may invert a complementary input signal INB in synchronization with a falling edge of a clock signal CLK (i.e., a rising edge of a complementary clock signal CLKB) to generate a first output signal OUT1.

The fourth buffer 33 may invert the first output signal OUT1 in synchronization with a rising edge of a clock signal CLK (i.e., a falling edge of a complementary clock signal CLKB) to generate a second complementary output signal OUTB2.

The first latch unit 34 may be coupled between a node ND31 and a node ND33 to latch voltage levels of the node ND31 and the node ND33. The first complementary output signal OUTB1 may be outputted through the node ND31, and the first output signal OUT1 may be outputted through the node ND33.

The second latch unit 35 may be coupled between a node ND32 and a node ND34 to latch voltage levels of the node ND32 and the node ND34. The second output signal OUT2 may be outputted through the node ND32, and the second complementary output signal OUTB2 may be outputted through the node ND34.

The first initialization element 36 may initialize the first complementary output signal OUTB1 in response to a complementary reset signal RSTB so that the first complementary output signal OUTB1 has a drive voltage VP. The second initialization element 37 may initialize the second output signal OUT2 in response to a reset signal RST so that the second output signal OUT2 has a ground voltage VSS. The third initialization element 38 may initialize the first output signal OUT1 in response to the reset signal RST so that the first output signal OUT1 has the ground voltage VSS. The fourth initialization element 39 may initialize the second complementary output signal OUTB2 in response to the complementary reset signal RSTB so that the second complementary output signal OUTB2 has the drive voltage VP.

As described above, the shift register according to an embodiment of the present invention may simultaneously change levels of the first output signal OUT1 and the first complementary output signal OUTB1 in synchronization with a falling edge of the clock signal CLK using the first and third buffers 30 and 32 and may simultaneously change levels of the second output signal OUT2 and the second complementary output signal OUTB2 in synchronization with a rising edge of the clock signal CLK using the second and fourth buffers 31 and 33. As such, the shift register according to an embodiment of the present invention may invert the input signal IN and the complementary input signal INB in sequential synchronization with a falling edge and a rising edge of the clock signal CLK, thereby stably generating the second output signal OUT2 and the second complementary output signal OUTB2 corresponding to differential output signals even in a high-speed operation.

What is claimed is:

1. A shift register comprising:
a first clock buffer configured to invert an input signal and a complementary input signal in response to a clock signal to generate a first output signal and a first complementary output signal; and
a second clock buffer configured to invert the first output signal and the first complementary output signal in response to the clock signal to generate a second output signal and a second complementary output signal.

2. The shift register of claim 1, wherein the first clock buffer inverts the input signal in synchronization with a first edge of the clock signal to generate the first complementary output signal and inverts the complementary input signal in synchronization with the first edge of the clock signal to generate the first output signal.

3. The shift register of claim 2, wherein the second clock buffer inverts the first output signal in synchronization with a second edge of the clock signal to generate the second complementary output signal and inverts the first complementary output signal in synchronization with the second edge of the clock signal to generate the second output signal.

4. The shift register of claim 3,
wherein the first edge of the clock signal is a falling edge of the clock signal; and
wherein the second edge of the clock signal is a rising edge of the clock signal.

5. The shift register of claim 3,
wherein the first output signal and the second output signal are initialized to have the same level; and
wherein the first complementary output signal and the second complementary output signal are initialized to have the same level.

6. The shift register of claim 1, wherein the first clock buffer includes:
a first buffer configured to invert the input signal in synchronization with a first edge of the clock signal to output the first complementary output signal through a first node; and
a second buffer configured to invert the complementary input signal in synchronization with the first edge of the clock signal to output the first output signal through a second node.

7. The shift register of claim 6, further comprising a first latch unit coupled between the first node and the second node to latch voltage levels of the first and second nodes.

8. The shift register of claim 7, further comprising:
a first initialization element configured to initialize the first node so that a voltage signal of the first node has a drive voltage; and
a second initialization element configured to initialize the second node so that a voltage signal of the second node has a ground voltage.

9. The shift register of claim 6, wherein the second clock buffer includes:
a third buffer configured to invert the first output signal in synchronization with a second edge of the clock signal to output the second complementary output signal through a third node; and
a fourth buffer configured to invert the first complementary output signal in synchronization with the second edge of the clock signal to output the second output signal through a fourth node.

10. The shift register of claim 9, further comprising a second latch unit coupled between the third node and the fourth node to latch voltage levels of the third and fourth nodes.

11. The shift register of claim 10, further comprising:
a third initialization element configured to initialize the third node so that a voltage signal of the third node has a drive voltage; and
a fourth initialization element configured to initialize the fourth node so that a voltage signal of the fourth node has a ground voltage.

12. A shift register comprising:
a first buffer configured to output a first complementary output signal, which is generated by inverting an input signal in synchronization with a first edge of the clock signal, through a first node;
a second buffer configured to output a second output signal, which is generated by inverting the first complementary output signal in synchronization with a second edge of the clock signal, through a second node;
a third buffer configured to output a first output signal, which is generated by inverting a complementary input signal in synchronization with the first edge of the clock signal, through a third node; and
a fourth buffer configured to output a second complementary output signal, which is generated by inverting the first output signal in synchronization with the second edge of the clock signal, through a fourth node.

13. The shift register of claim 12,
wherein the first edge of the clock signal is a falling edge of the clock signal; and
wherein the second edge of the clock signal is a rising edge of the clock signal.

14. The shift register of claim 12, further comprising a first latch unit configured to latch voltage levels of the first node and the third node.

15. The shift register of claim 14, further comprising a second latch unit configured to latch voltage levels of the second node and the fourth node.

16. The shift register of claim 15, further comprising a first initialization element configured to initialize the first node so that a voltage signal of the first node has a drive voltage.

17. The shift register of claim 16, further comprising a second initialization element configured to initialize the second node so that a voltage signal of the second node has a ground voltage.

18. The shift register of claim 17, further comprising a third initialization element configured to initialize the third node so that a voltage signal of the third node has the drive voltage.

19. The shift register of claim 18, further comprising a fourth initialization element configured to initialize the fourth node so that a voltage signal of the fourth node has the ground voltage.

20. The shift register of claim 19,
wherein the first and fourth initialization elements initialize the first and fourth nodes so that voltage signals of the first and fourth nodes have the drive voltage in response to a complementary reset signal; and
wherein the second and third initialization elements initialize the second and third nodes so that voltage signals of the second and third nodes have the ground voltage in response to a reset signal.
